(19) United States
(12) Patent Application Publication
(10) Pub. No.: US 2026/0202440 A1
(43) Pub. Date: Jul. 16, 2026

(54) PROBE CARD FOR A TESTING APPARATUS OF ELECTRONIC DEVICES WITH IMPROVED THERMAL MANAGEMENT

(71) Applicant: TECHNOPROBE S.P.A., Cernusco Lombardone (LC) (IT)

(72) Inventors: Stefano FELICI, Cernusco Lombardone (LC) (IT); Flavio MAGGIONI, Cernusco Lombardone (LC) (IT)

(73) Assignee: TECHNOPROBE S.P.A., Cernusco Lombardone (LC) (IT)

(21) Appl. No.: 19/136,459

(22) PCT Filed: Dec. 13, 2023
(86) PCT No.: PCT/EP2023/085659

§ 371 Date: Jun. 6, 2025

(30) Foreign Application Priority Data
Dec. 21, 2022 (IT) 102022000026175

(51) Int. Cl. G01R 1/073; G01R 1/067; G01R 31/28

(52) U.S. Cl. CPC G01R 1/07342; G01R 1/06783; G01R 31/2886

(57) ABSTRACT

A probe card configured to be mounted in a testing apparatus of electronic devices in contact with a test cell of the apparatus is described. The probe card includes at least one probe head that houses a plurality of contact probes and is arranged between a device under test and a space transformer, which is in turn in contact with a main board configured to be connected to the test cell and provided with a stiffener. Suitably, the probe card includes a heat dispersion device provided with at least one thermal pipe configured to thermally connect the probe card and the test cell and to realize a dispersion of a heat generated inside the probe card during the operation thereof.

### TECHNICAL FIELD

The present invention relates to a probe card of a testing apparatus of electronic devices integrated on a semiconductor wafer. The following description is made with reference to this field of application with the only purpose of simplifying the exposition thereof.

### BACKGROUND ART

As it is well known, a probe card is essentially a device adapted to electrically connect a plurality of contact pads of a microstructure, in particular an electronic device integrated on a wafer, with corresponding channels of a testing apparatus which performs the test thereof.

The test performed on integrated devices is used to detect and isolate defective devices as early as in the production phase. Normally, the probe cards are thus used for the electric test of the devices integrated on wafers or chips before cutting or singulating and assembling them inside a containment package.

A probe card comprises a probe head, in turn essentially including a plurality of movable contact elements or contact probes respectively provided with at least one end portion or contact tip adapted to abut onto a pad of a corresponding plurality of contact pads of the device under test. The terms end or tip mean here and below an end portion of said probes, being not necessarily pointed.

It is well known that the efficacy and reliability of a measuring test depends, among other factors, on creating a good electric connection between the device under test and the testing apparatus, indeed, and thus, on establishing an optimum probe/pad electric contact.

Among the types of probe heads used in the here-considered technical field for testing devices integrated on wafers, the so-called vertical probe heads are widespread, in which the contact probes are arranged substantially perpendicular to a plane on which the device under test lies.

In particular, a vertical probe head comprises a plurality of contact probes retained by at least one plate or guide, usually by a pair of plates or guides, which are substantially plate-shaped and parallel to each other. These guides are located at a certain distance from each other so as to leave a free space or air gap for the movement and possible deformation of the contact probes during the testing and they are provided with appropriate guide holes adapted to slidingly house said contact probes.

More particularly, the pair of guides comprises an upper guide (upper die) and a lower guide (lower die), both equipped with guide holes through which the contact probes axially slide, usually made by wires of special alloys with good electric and mechanical properties and in the field also indicated as needles, the term lower conventionally indicating the guide which is closer to the device under test.

The good connection between the contact probes of the probe head and the contact pads of the device under test is ensured by pressing the probe head on the device itself, the contact probes, which are movable inside the guide holes made in the upper and lower guides, undergoing, during said pressing contact, a bending, inside the air gap between the two guides, and a sliding inside the guide holes housing them.

The bending of the contact probes in the air gap can be also helped and guided through a suitable configuration of the probes themselves or of the guides, in particular using pre-deformed contact probes or suitably transversely shifting the guides comprising them, the transverse direction being the one which is substantially parallel to the plane of the device under test and of the guides.

In general, probe heads with probes that are not fixedly fastened, but kept interfaced to an appropriate main board, connected in turn to the testing apparatus are used: in that case they are referred to as unblocked probe heads. The main board is also indicated as main PCB, since it is usually made using the techniques of printed circuits or PCB (“Printed Circuit Board”), a technology that allows to form boards with active areas, comprising the contact pads, being even large-sized. The probe cards formed through the PCB technology have however major limitations with respect to a minimum reachable value for the distance (pitch) between the centres of the contact pads and, for this reason, the PCB technology is usually reserved just to form the main board, which has less stringent distance constraints between the pads than the device under test.

These less stringent distance constraints between the contact pads, and in particular the spacing of adjacent pads on the main board, are possible due to the use of an intermediate board or space transformer which has contact pads made on opposite faces thereof with centres at a different distance between a face and the opposite one, suitably connected with each other by means of connections, in particular metal tracks, made inside the space transformer itself.

In this case, the contact probes have a further end portion or contact head adapted to abut onto a plurality of contact pads made on a first face of said space transformer, in particular a face arranged towards the probe head and thus the device under test.

The good electric contact between contact probes and space transformer is ensured similarly to the contact with the device under test by pressing the probes, in particular the contact heads thereof, onto the contact pads made on the space transformer.

Furthermore, the main board is generally kept in place by means of a stiffener.

The assembly of the probe head, of the main board, of the intermediate board or space transformer and of the stiffener forms the probe card.

In the vertical probe technology, it is particularly important to ensure the good connection of the contact probes with the device under test, at the contact tips thereof, and with the testing apparatus, at the contact heads thereof and thus at the space transformer, which plays a very important role especially when testing integrated circuits made according to the most recent integration technologies which provide for contact pads on the devices under test which are extremely close and very small in size, constraints which are not compatible with the PCB technology through which the main board of the probe card is formed, as indicated above.

The mutual positioning of the elements composing the probe card also turns out to be an extremely important parameter for a correct operation of the probe card itself and the different technologies used to make said elements introduce flatness problems which complicate the configuration of the probe card as a whole and especially in connection with the mutual positioning of the intermediate board or space transformer and main board. Even the presence of the stiffener, which makes the whole assembly more rigid and resistant, unfortunately does not allow the flatness defects of the space transformer to be eliminated in a sufficient way and the correct and complete contact thereof with the main board to be ensured.

The whole thing is further complicated by the operating temperature of the probe card itself, in particular in case of testing operations at extreme temperatures. In that case, in fact, the thermal expansions of the elements composing the probe card can affect the correct behaviour thereof, due to the different thermal expansion coefficients of the different materials of which said elements are made. It is in fact usual to bind together the elements composing a probe card by means of screws, which, in particular during a temperature testing, apply to the different boards a constraint which tends to cause a buckle thereof, resulting in a malfunction of the probe card as a whole, even in the lack of contact of the contact probes of the probe head with the contact pads of the device under test. Moreover, during the testing operations, the contact probes heat up due to the passage of the several signals, increasing the heat which is present inside the probe head, in particular in case of a probe head provided with a very high number of contact probes.

Similarly, the abutment of said contact probes onto the pads of the space transformer and the transport of the signals therein produce an undesirable heat that accumulates in the probe card.

This problem is particularly felt in case of large-sized probe cards, such as for example the probe cards for the testing of memory devices such as DRAMs, or in general the probe cards for the multi-dice test. For this type of probe cards, the failure to control the thermal expansion of the components involves considerable problems during the test phase.

The technical problem of the present invention is to provide a probe card, having such structural and functional features as to allow to overcome the limitations and drawbacks still affecting the probe cards made with the known technologies, favouring the elimination of the heat which is produced during the testing operations and limiting the increase in the operating temperature of the probe card and the probe head contained therein, with an improved thermal management of said probe card and a control of the thermal expansion undergone by the elements composing them.

### DISCLOSURE OF INVENTION

The solution idea underlying the present invention is to provide the probe card with a heat dispersion device comprising suitable elements arranged for the thermal exchange and generally indicated as thermal pipes.

Based on this solution idea the technical problem is solved by a probe card configured to be mounted in a testing apparatus of electronic devices in contact with a test cell of said apparatus, the probe card comprising at least one probe head that houses a plurality of contact probes and is arranged between a device under test and a space transformer, which is in turn in contact with a main board configured to be connected to the test cell and provided with a stiffener. Suitably, the probe card comprises a heat dispersion device provided with at least one thermal pipe configured to thermally connect the probe card and the test cell and to realize a dispersion of a heat generated inside the probe card during the operation thereof.

More particularly, the invention comprises the following additional and optional features, taken individually or in combination if necessary.

According to an aspect of the invention, the at least one thermal pipe can be of the passive type and made of a material having a thermal conductivity greater than 100 W/(m·K), preferably greater than 500 W/(m·K).

More particularly, the at least one thermal pipe can be made of a material selected from copper, aluminum, aluminum nitride, silicon nitride, silicon carbide and CVD-D (Chemical Vapor Deposition-Diamond).

According to another aspect of the invention, the at least one thermal pipe can comprise a first end in thermal contact with the test cell, preferably resting on said test cell; the at least one thermal pipe can also comprise a second end in thermal contact with the main board, preferably resting on said main board.

More particularly, the first end of the at least one thermal pipe can be arranged at a portion of a first face of the stiffener in contact with the test cell; furthermore, the second end of the at least one thermal pipe can be arranged at a portion of a second face of the stiffener in contact with the main board.

According to another aspect of the invention, the second end of the at least one thermal pipe can be associated with a first face of the main board by one of the following methods: pressing contact, welding, gluing by thermal glue, seaming.

According to still another aspect of the invention, the main board can comprise at least one contact area formed on the first face and configured to form a support surface of the second end of the at least one thermal pipe.

According to a further aspect of the invention, the at least one thermal pipe can comprise a first end in thermal contact with the test cell, preferably resting on the test cell; said at least one thermal pipe can also comprise a second end in thermal contact with the space transformer, preferably resting on the space transformer; in particular, the at least one thermal pipe can pass through the main board.

In that case, the at least one thermal pipe can also comprise a reduced-diameter section, inside the main board and a section-changing point from which said reduced-diameter section develops, passing through the main board; the section-changing point is preferably arranged at a portion of the main board in contact with the stiffener.

According to another aspect of the invention, the at least one thermal pipe can be of the active type with heat transfer to liquid; in that case, the heat dispersion device can comprise at least one radiator associated with the at least one thermal pipe.

In particular, the at least one thermal pipe can have a first end associated with a first radiator; said first radiator can be arranged on the main board at a face thereof facing the test cell. The at least one thermal pipe can also have a second end associated with a second radiator; said second radiator can be arranged on the space transformer at a face thereof facing the probe head.

According to this aspect of the invention, the at least one thermal pipe can comprise, at the second end thereof, an evaporation chamber, in which a liquid flows, which is transformed into steam from the heat produced by the probe card; said at least one thermal pipe can also comprise a condensation chamber arranged at the first end thereof. The steam is thus transported along the at least one thermal pipe from the evaporation chamber towards the condensation chamber, in which the steam is again transformed into liquid, releasing the heat to the first radiator; the liquid returns then to the evaporation chamber.

According to another aspect of the invention, the at least one thermal pipe can comprise a first end in thermal contact with the test cell, preferably resting on said test cell; the at least one thermal pipe can also comprise a second end in thermal contact with the probe head.

According to this aspect of the invention, the second end of the thermal pipe can be inside a housing of the probe head.

In particular, said second end of the at least one thermal pipe can be in an air gap inside the probe head.

The heat dispersion device can further comprise a thermal storage element associated with the second end of the at least one thermal pipe.

According to another aspect of the invention, the heat dispersion device can further comprise a coating layer arranged on a guide of the probe head, preferably in contact with the second end of the at least one thermal pipe.

In particular, the coating layer can be made of a material having a thermal conductivity greater than 100 W/(m·K), preferably greater than 500 W/(m·K).

Furthermore, the coating layer can be made of a material selected from silicon nitride, silicon carbide and CVD-D (Chemical Vapor Deposition-Diamond).

According to still another aspect of the invention, the heat dispersion device can further comprise a core formed inside the space transformer. Suitably, the at least one thermal pipe can have a first end in thermal contact with the test cell and a second end in thermal contact with said core. The core can also be made of a material having a thermal conductivity greater than 100 W/(m·K), preferably greater than 500 W/(m·K).

According to this aspect of the invention, the core can comprise a peripheral portion exposed to the air outside the space transformer.

The core can be made in particular of a material having a Young's modulus value greater than 30000 MPa, preferably greater than 1200000 Mpa.

More particularly, the core can be made of a material selected from silicon nitride, silicon carbide and CVD-D (Chemical Vapor Deposition-Diamond), preferably CVD-D.

According to another aspect of the invention, the heat dispersion device can further comprise air-cooled heat exchange structures including at least one exchanger and a fan coil configured to generate cooling air for the exchanger; furthermore, the heat dispersion device can comprise a core made of a material having a thermal conductivity greater than 100 W/(m·K), preferably greater than 500 W/(m·K) and arranged inside the space transformer. In particular, the at least one thermal pipe can have a first end in thermal contact with the exchanger; furthermore, the at least one thermal pipe can have a second end in thermal contact with the core.

According to still another aspect of the invention, the heat dispersion device can further comprise liquid-cooled heat exchange structures including at least one microfluidic channel. The microfluidic channel can be formed inside the at least one thermal pipe and the space transformer; furthermore, the microfluidic channel can be passed through by a cooling liquid. The heat dispersion device can also comprise a core made of a material having a thermal conductivity greater than 100 W/(m·K), preferably greater than 500 W/(m·K) and arranged inside the space transformer; suitably, the at least one thermal pipe can have a first end at an end of the microfluidic channel and a second end in thermal contact with the core.

Finally, according to this aspect of the invention, the liquid-cooled heat exchange structures can include a plurality of microfluidic channels made inside the at least one thermal pipe and the space transformer.

The features and advantages of the probe card according to the invention will become apparent from the following description of exemplary embodiments thereof given by way of non-limiting examples with reference to the attached drawings.

### BRIEF DESCRIPTION OF DRAWINGS

In the drawings:

FIG. 1 shows a schematic sectional view of a probe card according to an embodiment of the invention;

FIG. 2 shows a schematic sectional view of a probe card according to an alternative embodiment of the invention;

FIG. 3A shows a schematic sectional view of a probe card according to a further alternative embodiment of the invention and FIGS. 3B-3D schematically show elements comprised in the probe card of FIG. 3A; and

FIGS. 4, 5, 6, 7, 8 and 9 show schematic sectional views of a probe card according to still further alternative embodiments of the invention.

### MODES FOR CARRYING OUT THE INVENTION

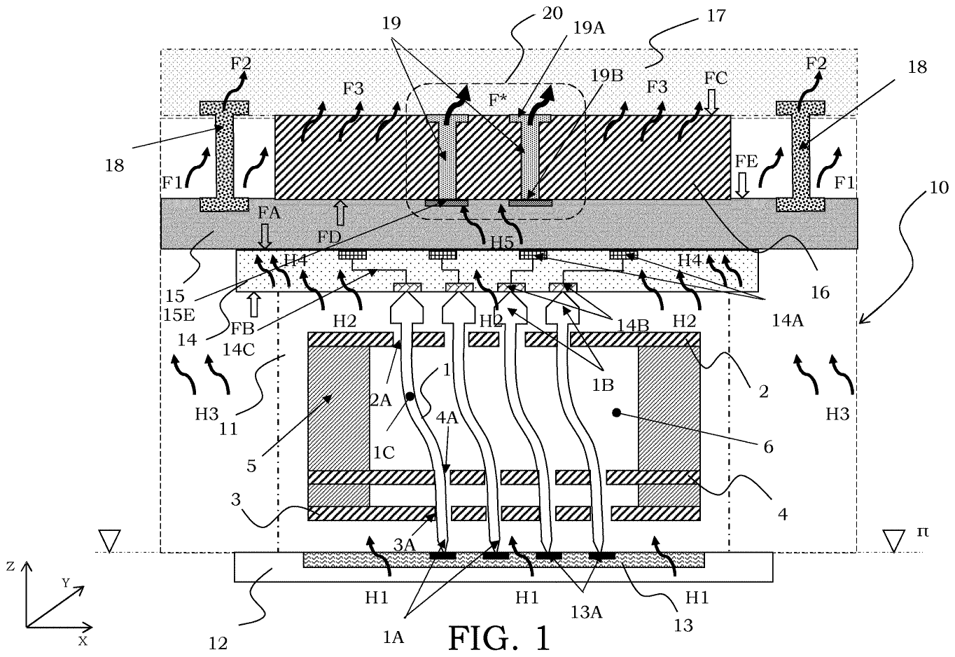

With reference to the figures, and particularly to FIG. 1, a probe card made according to the present invention and comprising at least one probe head provided with a plurality of contact probes for the test of electronic devices, in particular integrated on wafers, is globally indicated with 10.

It should be noted that the figures represent schematic views of the card according to the invention and are not drawn to scale, but instead they are drawn so as to emphasize the important features of the invention.

Moreover, the several aspects of the invention represented by way of example in the figures are obviously combinable with each other and interchangeable from one embodiment to another.

Furthermore, elements that are structurally and functionally identical in the several embodiments illustrated in the various figures and described hereinafter are indicated with the same alphanumeric references.

In the following description, relative terms such as “above”, “below”, “upward”, “downward”, “upper”, “lower” will be used referring to the illustrations of the solutions given in the figures, only to simplify the exposition thereof.

Finally, indications of particular geometries (circular, rectangular) or of the arrangement of the elements (parallel, orthogonal, contiguous) as well as the term “substantially” are always to be intended in connection with physical and not geometrically abstract elements, and thus they must always take into consideration the tolerances introduced by the transition from a pure mathematical/geometric world to the real world.

In particular, as illustrated in FIG. 1, the probe card 10 comprises a probe head 11 that houses a plurality of contact probes 1. The illustrated probe head 11 is of the unblocked probe vertical type and comprises at least one upper plate or guide 2 and one lower plate or guide 3, having respective upper guide holes 2A and lower guide holes 3A through which the contact probes 1 slide.

As it is conventional in the technical field of the present invention, the term “lower guide” indicates the guide arranged closer to a device under test and the term “upper guide” indicates the guide arranged closer to a testing apparatus connected to the probe card 10 that includes the probe head 11, when said probe card 10, and thus the probe head 11, is in the operating conditions, mounted like an end element of said testing apparatus.

In the example illustrated in FIG. 1, the probe head 11 also comprises an intermediate plate or guide 4, arranged parallel between the upper guide 2 and the lower guide 3, in particular closer to the latter, the intermediate guide 4 being similarly provided with intermediate guide holes 4A through which the contact probes 1 slide. Said three-guide embodiment is merely given by way of example, the probe head 11 being allowed to comprise any number of guides which is greater or equal to one.

The probe head 11 also comprises a containment element or housing 5, configured to make the upper guide 2, the lower guide 3 and the intermediate guide 4 integral with each other and to encompass the contact probes 1, a free space or air gap 6 being defined inside the housing 5, in particular between the upper guide 2 and the intermediate guide 4, said air gap 6 allowing a bending and deformation of the contact probes 1 during the operation of the probe head 11.

Each of the contact probes 1 comprises at least one first end portion or contact tip 1A configured to abut onto a corresponding contact pads 13A of a device under test 13, in particular integrated on a semiconductor wafer 12, so as to establish the desired contact, in particular an electric contact, between the contact probes 1 of the probe head 11 and the contact pads 13A of the device under test 13.

Each contact probe 1 further comprises a second end portion or contact head 1B configured to establish the contact with a main board 15 or main PCB for connection with a plate of a testing apparatus, also indicated as test cell 17. A rod-shaped probe body 1C is arranged between the contact head 1B and the contact tip 1A and substantially arranged along a longitudinal development direction of the contact probe 1, that is in particular orthogonal to a plane π on which the semiconductor wafer 12 is arranged, where the device under test 13 is integrated, that is along the z axis of the local reference of FIG. 1.

The upper guide 2, the lower guide 3 and the intermediate guide 4 are plate-shaped elements arranged parallel to each other and to the plane π of the semiconductor wafer 12 and thus of the device under test 13. Suitably, as seen in connection with the prior art, said upper guide 2, lower guide 3 and intermediate guide 4 are shifted from each other, along a direction that is tangential to the plane π of the semiconductor wafer 12 that is along the x axis of the local reference of FIG. 1, so as to impose a preferential bending direction to the contact probes 1. By virtue of this shift of the guides, the guide holes formed therein and housing a same contact probe turn out not to be aligned with each other with respect to a direction which is orthogonal to the plane π of the semiconductor wafer 12, that is along the z axis of the local reference of FIG. 1, which forces a bending in the probe body 1C of the contact probes 1 and determines said preferential bending direction thereof.

The probe card 10 further comprises an intermediate plate arranged between the probe head 11 and the main board 15 and configured to perform a spatial transformation, in particular in connection with the distribution of contact pads on the opposite faces thereof and for this reason indicated as space transformer 14.

The space transformer 14 has a first face FA facing the main board 15, that is an upper face according to the local reference of FIG. 1, comprising a first plurality of contact pads, also indicated as tester side pads 14A. The space transformer 14 further has a second face FB facing the probe head 11, that is a lower face according to the local reference of FIG. 1, comprising a second plurality of contact pads, also indicated as probe side pads 14B, onto which the contact heads 1B of the contact probes 1 abut, the probe side pads 14B being connected to the tester side pads 14A by suitable metallizations or metal tracks 14C made inside the space transformer 14.

Finally, the probe card 10 comprises a stiffener 16 associated with the main board 15 and configured to improve the flatness thereof and to avoid the curvature thereof, in particular in case of an increase in temperature during the operation of the probe card 10, that is during the testing operations.

Furthermore, connectors 18, in particular clamping screws, are used to make the test cell 17 integral with the probe card 10, in particular with the main board 15.

During the operation of the probe card 10, that is during the test of the devices under test 13 integrated on the semiconductor wafer 12, the several elements composing the probe card 10 become sources of heat flows and in particular:
a first heat flow H1 is exchanged between the semiconductor wafer 12, in particular the devices under test 13 integrated therein, and the probe head 11;
a second heat flow H2 is exchanged between the probe head 11 and the space transformer 14;
a third heat flow H3 is exchanged between the probe head 11 and the main board 15, through the air surrounding the probe head 11 inside the probe card 10;
a fourth heat flow H4 develops inside the space transformer 14 and moves towards the main board 15; and
a fifth heat flow H5 develops inside the main board 15 and moves towards the stiffener 16.

The first heat flow H1 is defined as functional and is related to the testing operations and to the signals which are exchanged by the contact probes 1 of the probe head 11, transmitted on the contact pads 13A of the devices under test 13 integrated on the semiconductor wafer 12 to perform the test of said devices.

The second heat flow H2 is due to the heating of the contact probes 1 inside the probe head 11 due to the Joule effect, always due to the signals which pass through said probes and which transfers to the space transformer 14 mainly by virtue of the contact of the contact heads 1B of said contact probes 1 with the probe side pads 14B of the space transformer 14.

The third heat flow H3 is related to the heating of the air inside the probe card 10, in particular by virtue of a transferring from the support structure (chuck) of the semiconductor wafer 12 which, during the testing operations, overheats.

The fourth heat flow H4 and the fifth heat flow H5 develop, always due to the Joule effect, inside the space transformer 14 and the main board 15, respectively, by virtue of the signals transported inside said elements.

Other elements of the probe card 10 are instead in charge of a heat dispersion and in particular:
a first heat dispersion flow F1 is generated by virtue of the air which is present between the main board 15 and the test cell 17 and moves towards the test cell 17;
a second heat dispersion flow F2 is generated by the connectors 18 and moves towards the test cell 17; and
a third heat dispersion flow F3 establishes between the stiffener 16 and the test cell 17, at a contact area between said elements, the third heat dispersion flow F3 also moving towards the test cell 17.

The space transformer 14 and the probe head 11 turn out to be the elements comprised in the probe card 10 which are more exposed to stress by high temperatures.

Advantageously according to the present invention, the probe card 10 further comprises a heat dispersion device 20 which is able to improve the thermal exchange of the probe card 10 and reduce the problems related to the overheating of the elements thereof.

According to a first embodiment illustrated in FIG. 1, the heat dispersion device 20 comprises at least one thermal pipe 19, in the example of the figure a pair of thermal pipes 19 arranged inside the stiffener 16 and able to put the main board 15 and the test cell 17 in thermal contact. It is obvious that the presence of two thermal pipes 19 in the heat dispersion device 20 is merely given by way of non-limiting example, said heat dispersion device 20 being allowed to comprise any number, greater than one, of thermal pipes 19.

In particular, each thermal pipe 19 comprises a first end 19A in thermal contact with the test cell 17, preferably resting on said test cell 17, and a second end 19B in thermal contact with the main board 15, preferably resting on said main board 15. The first end 19A is arranged at a first face FC of the stiffener 16, in particular an upper face considering the local reference of FIG. 1, that is facing the test cell 17, and the second end 19B is arranged at a second face FD of the stiffener 16, in particular a lower face considering the local reference of FIG. 1, that is facing the main board 15. Each thermal pipe 19 is positioned so that the first end 19A is located at a portion of the first face FC of the stiffener 16 in contact with the test cell 17 and the second end 19B is located at a portion of the second face FD of the stiffener 16 in contact with the main board 15, so as to realize a thermal connection between the main board 15 and the test cell 17. Furthermore, the first end 19A has an enlarged support configuration on the first face FC of the stiffener 16.

Suitably, the thermal pipes 19 of the heat dispersion device 20 generate an additional heat dispersion flow F* which is able to significantly improve the dispersion of the heat produced inside the probe card 10. For this purpose, the thermal pipes 19 are suitably made of materials having a high thermal conductivity λ, selected from metal or inorganic materials.

Preferably, the thermal pipes 19 are made of a material having a thermal conductivity λ greater than 100 W/(m·K), preferably greater than 500 W/(m·K).

More particularly, the thermal pipes 19 can be made of a material selected from copper, aluminum, aluminum nitride, silicon nitride, silicon carbide and CVD-D (Chemical Vapor Deposition-Diamond).

The second end 19B of each thermal pipe 19 is resting on a first face FE of the main board 15, in particular an upper face according to the local reference of FIG. 1, said first face FE of the main board 15 being in contact with the second face FD of the stiffener 16. As an alternative, the second end 19B can be welded or glued by a thermal glue or even made integral by seaming (crimping) with said first face FE of the main board 15.

In a preferred embodiment, the thermal pipes 19 are formed by columns of metal, for example copper, crimped to realize indeed a composite material, which is thus lapped at the first and second ends 19A, 19B of said thermal pipe 19 to have a final planar configuration and a monolithic block with increased vertical thermal conductivity.

Furthermore, appropriate contact areas or thermal pads 15E can be arranged on the first face FE of the main board 15 to form support surfaces of the second ends 19B of the thermal pipes 19.

It is emphasized that, thanks to the presence of the heat dispersion device 20 and of the thermal pipes 19 thereof which thermally connect the main board 15 and the test cell 17, an increase in the thermal conductivity of the main board 15 with an improved dispersion of the heat produced by the probe card 10 during the operation thereof is substantially achieved.

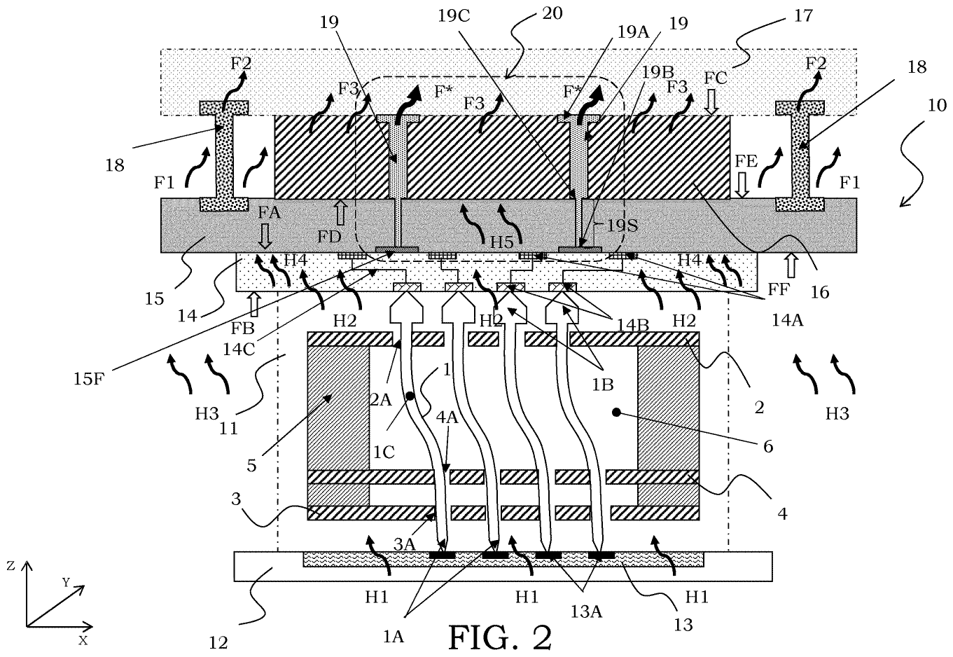

According to an alternative embodiment, the thermal pipes 19 of the heat dispersion device 20 can be formed so as to completely pass through the main board 15 and thermally contact the space transformer 14, as schematically illustrated in FIG. 2.

Moreover, it is possible to form each thermal pipe 19 so as to comprise a reduced-diameter section 19S, inside the main board 15. In that case, each thermal pipe 19 comprises a first end 19A arranged at the first face FC of the stiffener 16 and a second end 19B arranged at a second face FF, opposite the first face FE, of the main board 15, in particular a lower face according to the local reference of FIG. 2, said second face FF being in contact with the space transformer 14, as well as a section-changing point 19C, arranged at the first face FE of the main board 15, from which the reduced-diameter section 19S develops, passing through the main board 15.

In that case, appropriate contact areas or thermal pads 15F can also be arranged on the second face FF of the main board 15 to form support surfaces of the second ends 19B of the thermal pipes 19.

The thermal pipes 19 are suitably made of materials having a high thermal conductivity λ, selected from metal or inorganic materials, said materials having a thermal conductivity λ greater than 100 W/(m·K), preferably greater than 500 W/(m·K) and being selected from copper, aluminum, aluminum nitride, silicon nitride, silicon carbide and CVD-D (Chemical Vapor Deposition-Diamond), as indicated above.

Thermal pipes 19 as described above in connection with the embodiments of FIGS. 1 and 2, substantially in the form of rods of solid metal, are commonly indicated as passive thermal pipes.

It is also possible to use thermal pipes 19 of the active type, with heat transfer to liquid. In that case, the heat dispersion device 20 comprises, besides at least one thermal pipe 19, at least one radiator, associated with the thermal pipe 19, for transferring the heat outside the thermal pipe 19 itself.

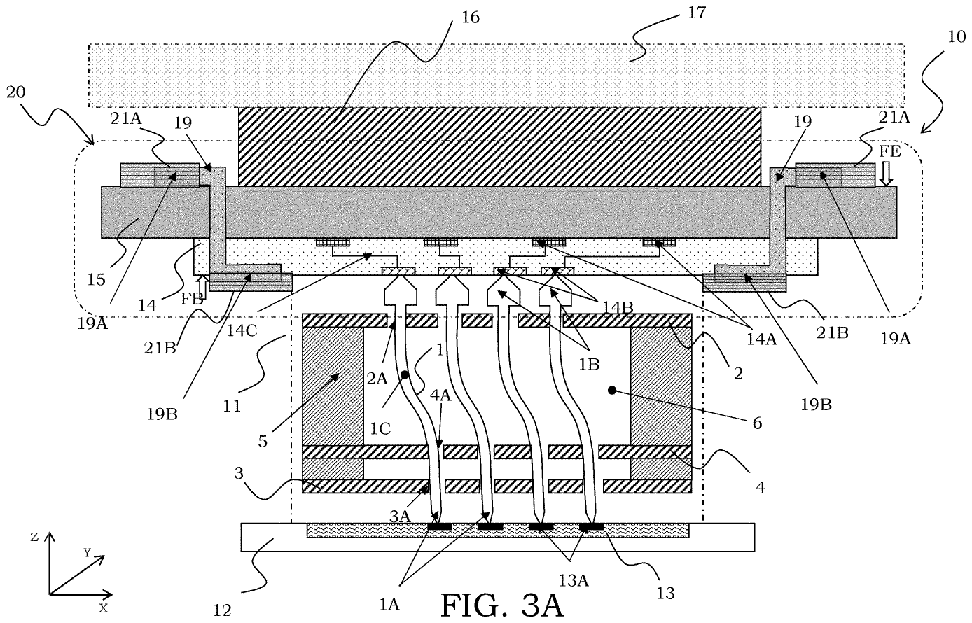

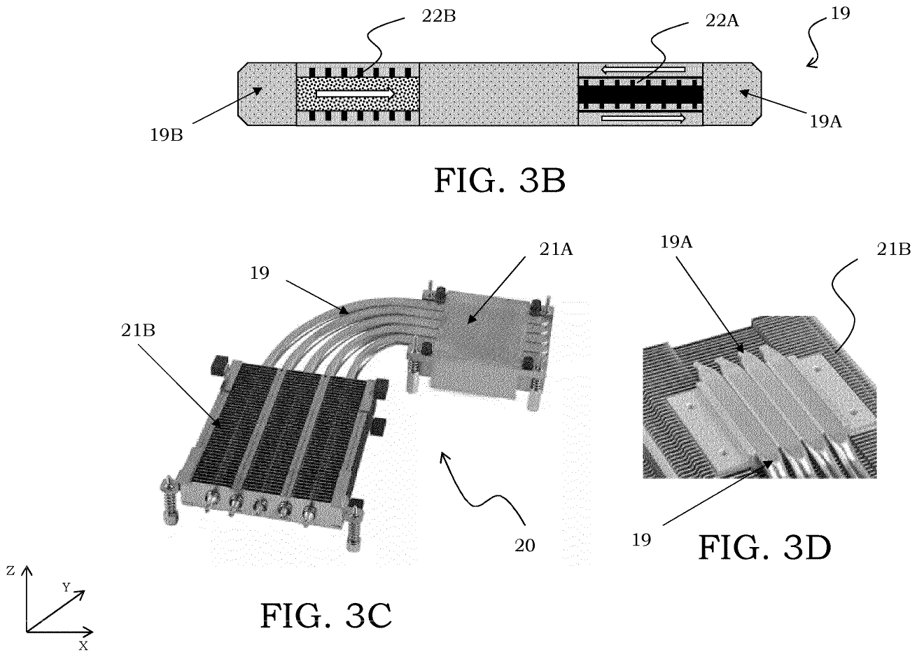

More particularly, in the example illustrated in FIG. 3A, the heat dispersion device 20 comprises a pair of thermal pipes 19, each thermal pipe 19 having a first end 19A associated with a first radiator 21A arranged on the main board 15, in particular at the first face FE thereof facing the test cell 17, and a second end 19B associated with a second radiator 21B arranged on the space transformer 14, in particular at the second face FB thereof facing the probe head 11. Suitably, the first radiator 21A is positioned in a portion of the first face FE of the main board 15 in which the same is not in contact with the stiffener 16 and the second radiator 21B is positioned in a portion of the second face FB of the space transformer 14 in which there are not the probe side pads 14B onto which the contact heads 1B of the contact probes 1 of the probe head 11 abut, so as not to interfere with the operation of the probe card 10 and of the probe head 11 comprised therein.

Each active thermal pipe 19 comprises, as schematically illustrated in FIG. 3B, at its second end 19B, an evaporation chamber 22B, in which a liquid flows, which is transformed into steam from the heat produced by the probe card 10 and is transported along the thermal pipe 19 towards a condensation chamber 22A arranged at the first end 19A, in which the steam is again turned into liquid, releasing the heat to the first radiator 21A arranged on the main board 15, the liquid then returning to the evaporation chamber 22B to restart the process.

The so-obtained heat dispersion device 20 is schematically illustrated in FIG. 3C, comprising thermal pipes 19 arranged between the first radiator 21A and the second radiator 21B, the first radiator 21A being also illustrated in more detail in FIG. 3D, in which the second ends 19B of the thermal pipes 19 associated with said second radiator 21B are also shown.

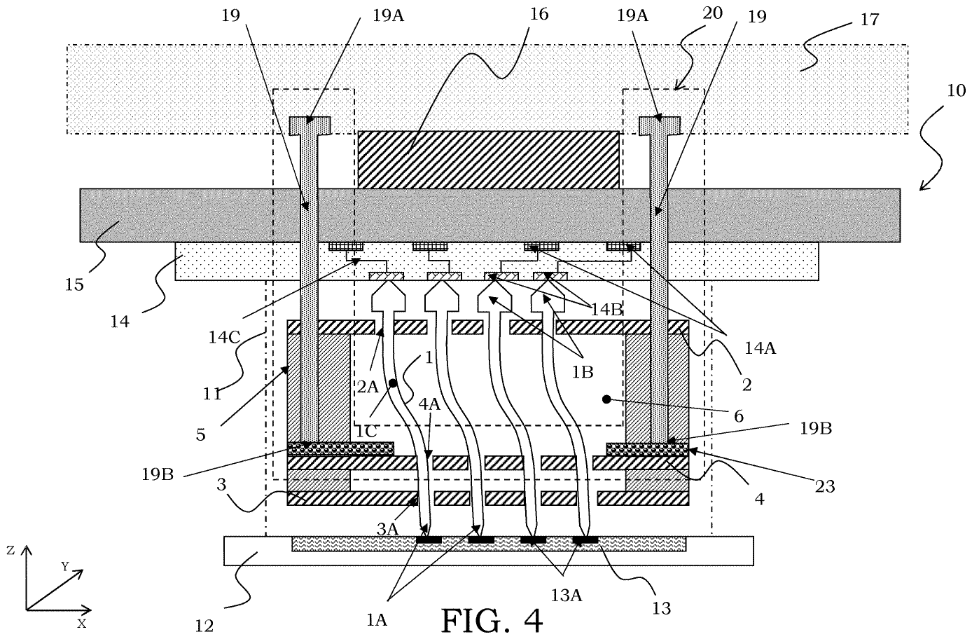

According to a further alternative embodiment, schematically illustrated in FIG. 4, the thermal pipes 19 can also be formed so as to penetrate the housing 5 of the probe head 11 and be in thermal contact therewith, so as to eliminate the heat produced in the probe head 11 and cool the housing 5 itself. In particular, in that case the second end 19B of the thermal pipes 19 is arranged inside the housing 5.

It is also possible to form the heat dispersion device 20 so as to further comprise a coating layer 23, made of a material having a high thermal conductivity λ, that is greater than 100 W/(m·K), preferably greater than 500 W/(m·K), arranged on one of the guides of the probe head 11 (also at the housing 5) in contact with the second end 19B of the thermal pipes 19. More particularly, the coating layer 23 can be made of a material selected from silicon nitride, silicon carbide and CVD-D (Chemical Vapor Deposition-Diamond).

In the example of FIG. 4, the coating layer 23 is arranged at a face of the intermediate guide 4, in particular an upper face considering the local reference of FIG. 4, and also develops at the housing 5, the second end 19B of each thermal pipe 19 being in thermal contact with said coating layer 23 inside the housing 5.

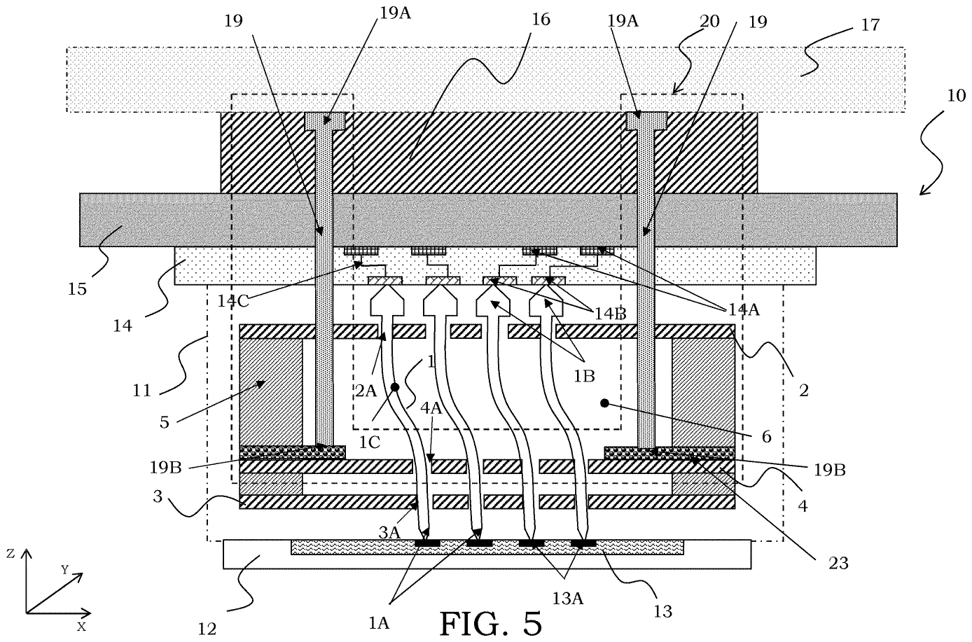

As an alternative, as schematically illustrated in FIG. 5, the thermal pipes 19 can be formed outside the housing 5 but inside the probe head 11, at the air gap 6. In particular, the second end 19B of said thermal pipes 19 is arranged inside said air gap 6, suitably in an area in which the thermal pipe 19 does not risk of coming into contact with the contact probes 1 during the normal operation of the probe card 10, thus even when said contact probes 1 bend and deform upon the pressing contact of their contact tips 1A on the contact pads 13A of the device under test 13. In that case too, it is possible to provide a coating layer 23, made of a material having a high thermal conductivity λ, that is greater than 100 W/(m·K), preferably greater than 500 W/(m·K), which can be made of a material selected from silicon nitride, silicon carbide and CVD-D (Chemical Vapor Deposition-Diamond) and arranged on one of the guides of the probe head 11 in contact with the second end 19B of the thermal pipes 19.

In the example of FIG. 5, the coating layer 23 is arranged at a face of the intermediate guide 4, in particular an upper face considering the local reference of FIG. 5, the second end 19B of each thermal pipe 19 being in thermal contact with said coating layer 23 inside the air gap 6, preferably in pressing contact on said coating layer 23 which also extends at said air gap 6. Although not illustrated in the figures, it is possible to form the coating layer 23 on the portion of the intermediate guide 4 which is located in the air gap 6, without said coating layer 23 extending also at the housing 5.

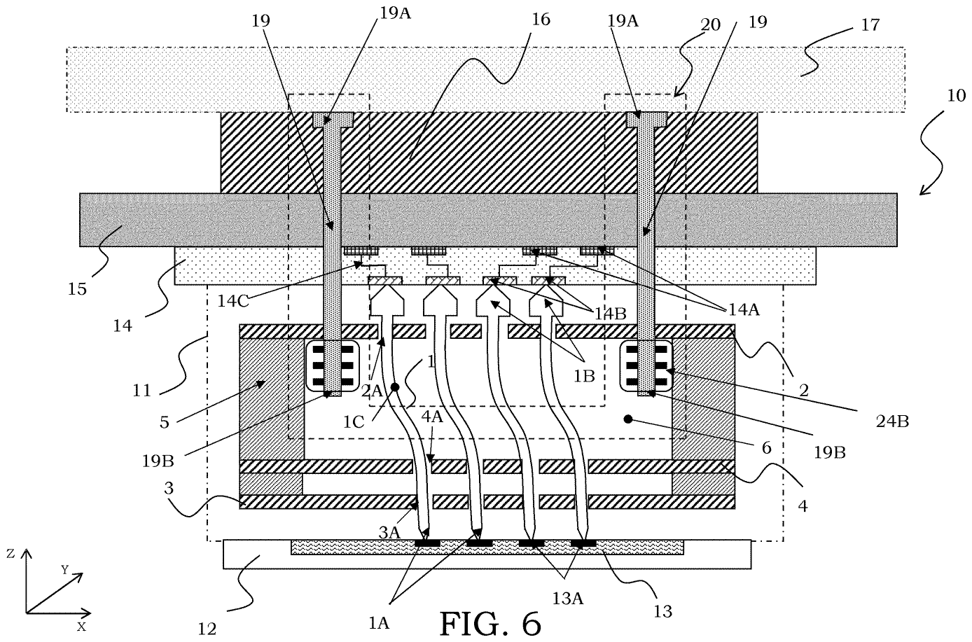

It is also possible to form the heat dispersion device 20 so as to comprise thermal pipes 19 configured with the second end 19B arranged inside the air gap 6, associated with a thermal storage element 24B, for example arranged at one of the guides of the probe head 11, such as the upper guide 2, as illustrated in FIG. 6. In particular, in the example of FIG. 6, the thermal storage element 24B is arranged on a face of a guide facing into the air gap 6, more particularly a lower face of the upper guide 2, considering the local reference of FIG. 6.

Suitably, said thermal storage element 24B helps in collecting the heat generated inside the probe head 11 for the subsequent elimination thereof, improving the thermal management of the probe card 10 as a whole. In that case too, it is possible to provide for the use of a coating layer having a high thermal conductivity (not illustrated in FIG. 6) associated with one of the guides, for example the intermediate guide 4 as in the examples of FIGS. 4 and 5, to improve the heat transfer inside the probe head 11 towards the thermal pipes 19 and in particular towards the thermal storage element 24B which faces on said intermediate guide 4.

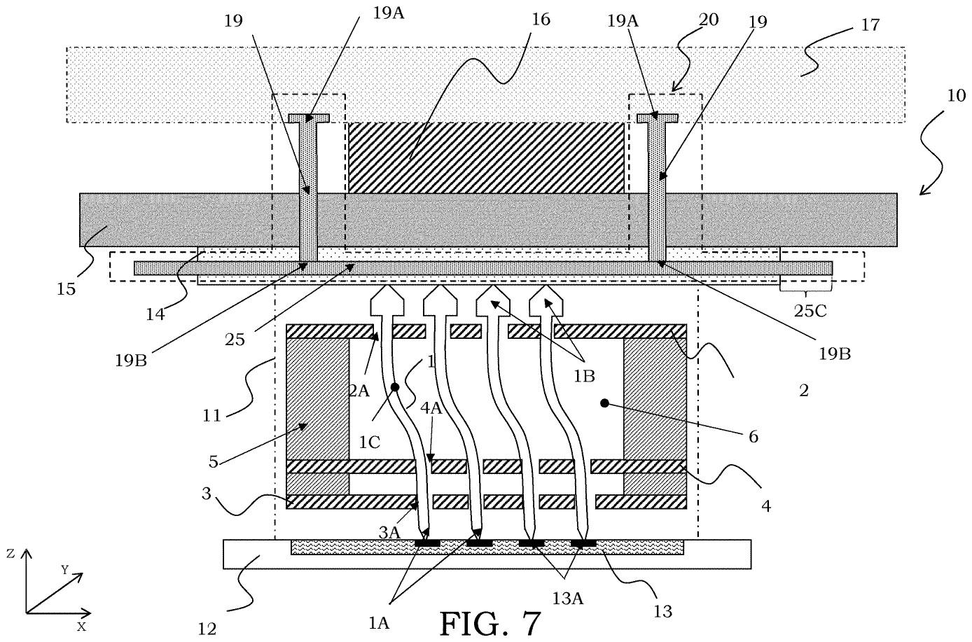

In a further alternative embodiment illustrated in FIG. 7, the heat dispersion device 20 comprises a core 25 formed inside the space transformer 14; in particular, said space transformer 14 can be in the form of a multilayer and comprise the core 25. Suitably, said core 25 is made of a material having a high thermal conductivity λ, that is having a thermal conductivity λ greater than 100 W/(m·K), preferably greater than 500 W/(m·K). Moreover, the second ends 19B of the thermal pipes 19 are formed so as to be in thermal contact with said core 25, which improves the heat transfer from inside the space transformer 14 towards the thermal pipes 19.

It is also possible to form the core 25 so as to comprise a peripheral portion 25C exposed with respect to the space transformer 14, that is to the other layers composing said space transformer 14 if in the form of a multilayer, said peripheral portion 25C further helping the heat dispersion from inside the space transformer 14 thanks to its contact with the air surrounding the probe card 10. According to an alternative non-illustrated embodiment, conductive layers can be arranged on the opposite surfaces of the exposed peripheral portion 25C of the core 25, so as to further ease the heat dispersion in the air.

The presence of the core 25 made of a material having a high thermal conductivity allows in particular to obtain an optimum collection and subsequent dispersion of the heat produced in the space transformer 14 during the testing operations performed by the probe card 10, also helping the collection and dispersion of the heat generated in the probe head 11, in particular thanks to the connection with said space transformer 14 of the contact probes 1 contained therein.

Suitably, the core 25 can be made of a material having a high stiffness, that is a high value of the modulus of tensile elasticity or Young's modulus E, in particular greater than 30000 MPa, preferably greater than 1200000 MPa, so as to be a mechanical support for the space transformer 14, which can comprise a plurality of layers suitably overlapping each other and the core 25, said plurality of layers being mechanically supported by the core 25 indeed.

Moreover, the core 25 is made of a non-conductive material, so as not to interfere with the electric operation of the space transformer 14.

The core 25 can be made in particular of silicon nitride, silicon carbide or CVD-D (Chemical Vapor Deposition-Diamond), preferably CVD-D, substantially dielectric materials, having a high thermal conductivity λ and having a stiffness which is sufficient to support the layers of the space transformer 14, in particular organic layers configured to form an organic multilayer (MLO) or metal and ceramic layers to form a ceramic-based multilayer or MLC (Multi Layer Ceramic).

The core 25 itself can be also formed by a plurality of layers of different materials, joined together, so as to improve the mechanical performances of said core 25 while ensuring a good level of thermal exchange. Among the materials used to form the different layers of the core 25 silicon nitride, silicon carbide and CVD-D (Chemical Vapor Deposition-Diamond) may be equally used, to mention a few.

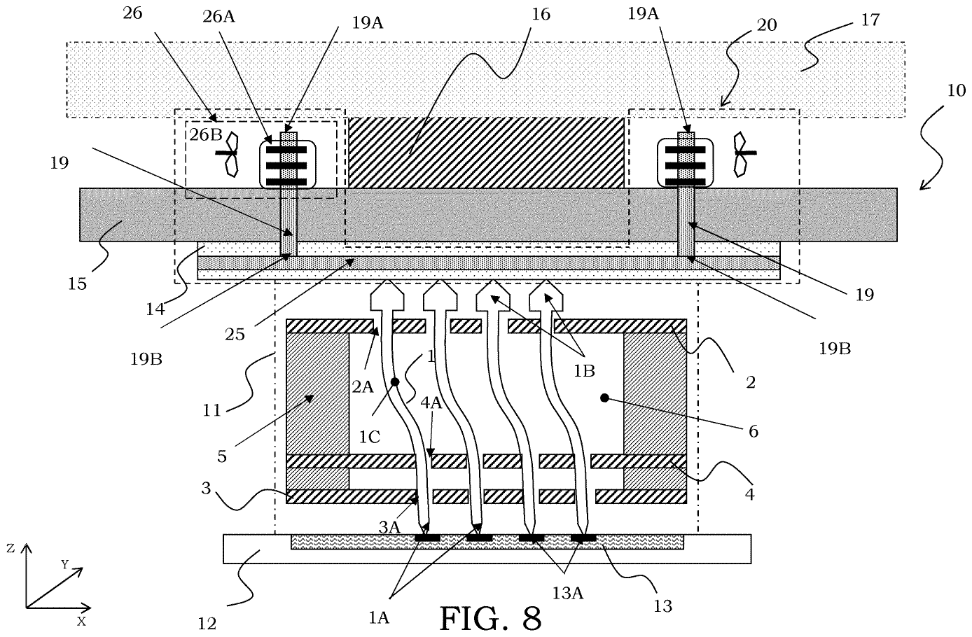

Furthermore, as schematically illustrated in FIG. 8, the heat dispersion device 20 can also comprise air-cooled heat exchange structures 26, essentially including an exchanger 26A at the first end 19A of the thermal pipes 19 and a corresponding fan coil 26B configured to generate cooling air for said exchanger 26A. In the example illustrated in FIG. 8, the thermal pipes 19 have in particular the second end 19B in thermal contact with the core 25 formed in the space transformer 14, preferably resting on said core 25.

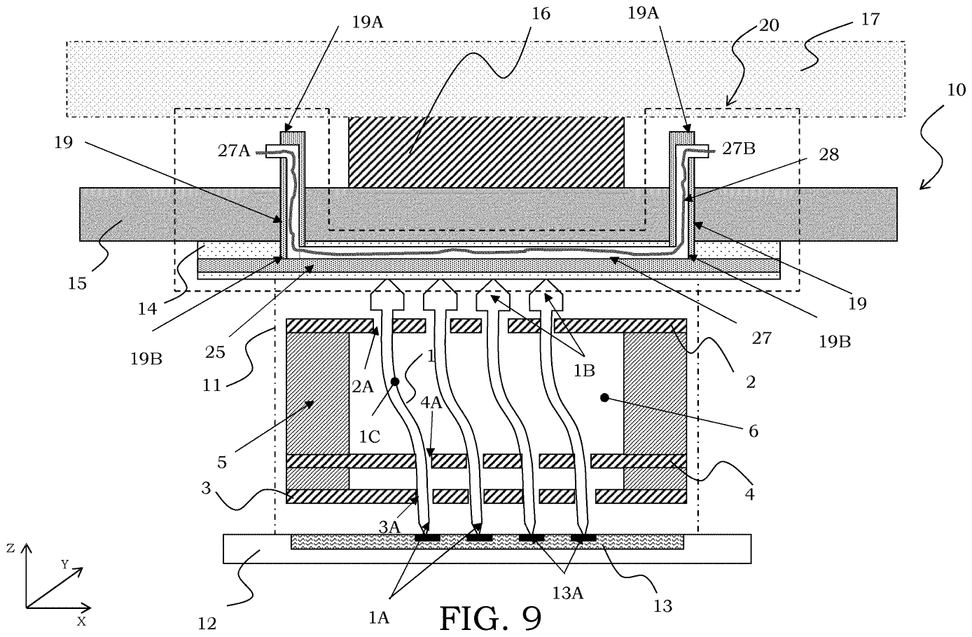

As an alternative, as schematically illustrated in FIG. 9, the heat dispersion device 20 can comprise liquid-cooled heat exchange structures, in the form of a microfluidic channel 27 formed inside the thermal pipes 19 and the space transformer 14 and passed through by a cooling liquid 28 from an inlet nozzle 27A to an outlet nozzle 27B, preferably formed at first ends 19A of different thermal pipes 19. In the example illustrated in FIG. 9, the thermal pipes 19 have the respective second ends 19B in thermal contact with the core 25 formed in the space transformer 14, preferably resting on said core 25.

The microfluidic channel 27 which passes through the thermal pipes 19 and the space transformer 14 for letting the cooling liquid 28 pass can be formed by laser drilling. Preferably, said microfluidic channel 27 is formed close to the core 25 so as to improve the thermal exchange therewith.

The presence of the cooling liquid 28 transported by the microfluidic channel 27 allows to realize a liquid cooling which affects the whole space transformer 14, besides the thermal pipes 19, which is thus able to significantly improve the efficiency of the thermal exchange realized by said space transformer 14, in particular by the core 25 thereof.

It is obviously possible to provide a plurality of microfluidic channels arranged in the thermal pipes 19 and in the space transformer 14 for transporting the cooling liquid 28.

In conclusion, advantageously according to the invention, the probe card provided with a heat dispersion device comprising thermal pipes is able to effectively disperse a heat produced in the probe card due to the test of an integrated device, if any, especially in case of testing operations using power signals. The probe card as a whole has thereby an improved thermal management, which allows to reduce the malfunctioning issues due to the deformations of the elements composing it caused by the heat produced inside the probe card during the operation thereof.

Such a probe card turns out thus to be suitable for applications in which the testing operations considerably heat the card as a whole, ensuring a correct operation thereof and avoiding any deformation of the elements composing it, such as for example the probe head and the space transformer, deformation which could affect the good outcome of the test.

The heat dispersion turns out to be further improved in the case in which the heat dispersion device comprises active thermal pipes associated with heat dissipators. Furthermore, the temperature performances of the probe card are improved when the heat dispersion device comprises air-or liquid-cooled heat exchange structures.

Moreover, the use in the probe card of a space transformer provided with a core made of a material having a high conductivity, possibly comprising a peripheral portion exposed to the air, improves the thermal exchange of the probe card as a whole; if the core is suitably made of a material having a sufficient stiffness, it is also able to form a mechanical support for other layers, in particular organic ones, which can form the space transformer itself.

Obviously, in order to meet contingent and specific requirements, a person skilled in the art will be allowed to bring several modifications and alternatives to the above-described probe card, all falling within the scope of protection of the invention as defined by the following claims.

1. A probe card configured to be mounted in a testing apparatus of electronic devices in contact with a test cell of said apparatus, comprising:
a probe head that houses a plurality of contact probes
a space transformer; and
a main board configured to be connected to the test cell and provided with a stiffener
the probe head being arranged between a device under test and the space transformer,
the space transformer being in contact with the main board,
wherein the probe card further comprises a heat dispersion device provided with a thermal pipe configured to thermally connect the probe card and the test cell and to realize a dispersion of a heat generated inside the probe card during the operation thereof.

2. The probe card according to claim 1, wherein the thermal pipe is of the passive type and made of a material selected from the group consisting of: a material having a thermal conductivity greater than 100 W/(m·K), and a material having a thermal conductivity greater than 500 W/(m·K).

3. (canceled)

4. The probe card according to claim 2, wherein the thermal pipe is made of a material selected from the group consisting of: copper, aluminum, aluminum nitride, silicon nitride, silicon carbide and CVD-D (Chemical Vapor Deposition-Diamond).

5. The probe card according to claim 2, wherein the thermal pipe comprises a first end in thermal contact with the test cell and a second end in thermal contact with the main board and has a configuration selected from the a group consisting of: a configuration wherein the first end rests on the test cell and the second end rests on the main board and a configuration wherein the first end of the thermal pipe is arranged at a portion of a first face of the stiffener in contact with the test cell and the second end of the thermal pipe is arranged at a portion of a second face of the stiffener in contact with the main board.

6. (canceled)

7. (canceled)

8. The probe card according to claim 5, wherein the second end of the thermal pipe is associated with a first face of the main board by a method selected from the group consisting of: pressing contact, welding, gluing by thermal glue, seaming and the main board comprises a contact area formed on the first face and configured to form a support surface of the second end of the thermal pipe.

9. (canceled)

10. The probe card according to claim 2, wherein the thermal pipe comprises a first end in thermal contact with the test cell and a second end in thermal contact with the space transformer, the thermal pipe passing through the main board and has a configuration selected from the group consisting of: a configuration wherein the first end rests on the test cell and the second end rests on the space transformer, a configuration wherein the thermal pipe comprises a reduced-diameter section, inside the main board and a section-changing point from which the reduced-diameter section develops, passing through the main board and a configuration wherein the thermal pipe comprises a reduced-diameter section, inside the main board and a section-changing point from which the reduced-diameter section develops, passing through the main board and the section-changing point is arranged at a portion of the main board in contact with the stiffener.

11. (canceled)

12. (canceled)

13. (canceled)

14. The probe card according to claim 1, wherein the thermal pipe is of the active type with heat transfer to liquid and the heat dispersion device comprises a radiator associated with the thermal pipe.

15. The probe card according to claim 14, wherein the thermal pipe has a first end associated with a first radiator arranged on the main board at a face thereof facing the test cell and a second end associated with a second radiator arranged on the space transformer at a face thereof facing the probe head.

16. The probe card according to claim 15, wherein the thermal pipe comprises, at the second end thereof, an evaporation chamber, in which a liquid flows, which is transformed into steam from the heat produced by the probe card and is transported along the thermal pipe towards a condensation chamber arranged at the first end of the thermal pipe, in which the steam is again turned into liquid, releasing the heat to the first radiator, the liquid then returning to the evaporation chamber.

17. The probe card according to claim 2, wherein the thermal pipe comprises a first end in thermal contact with the test cell and a second end in thermal contact with the probe head and has a configuration selected from the group consisting of: a configuration wherein the second end of the thermal pipe is positioned inside a housing of the probe head, a configuration wherein the second end of the thermal pipe is positioned in an air gap inside the probe head and a configuration wherein the second end of the thermal pipe is positioned in an air gap inside the probe head and the heat dispersion device further comprises a thermal storage element associated with the second end of the thermal pipe.

18. (canceled)

19. (canceled)

20. (canceled)

21. The probe card according to claim 17, wherein the heat dispersion device further comprises a coating layer having a configuration selected from the group consisting of: a configuration wherein the coating layer is arranged on a guide of the probe head and a configuration wherein the coating layer is in contact with the second end of the thermal pipe.

22. (canceled)

23. The probe card according to claim 21, wherein the coating layer is made of a material selected from the group consisting of: a material having a thermal conductivity greater than 100 W/(m·K) and a material having a thermal conductivity greater than 500 W/(m·K).

24. (canceled)

25. The probe card according to claim 23, wherein the coating layer is made of a material selected from the group consisting of: silicon nitride, silicon carbide and CVD-D (Chemical Vapor Deposition-Diamond).

26. The probe card according to claim 2, wherein the heat dispersion device further comprises a core formed inside the space transformer, the thermal pipe having a first end in thermal contact with the test cell and a second end in thermal contact with the core, the core being made of a material having a thermal conductivity greater than 100 W/(m·K).

27. The probe card according to claim 26, wherein the core comprises a peripheral portion exposed to the air outside the space transformer.

28. The probe card according to claim 26, wherein the core is made of a material having a value of the Young's modulus greater than 30000 MPa.

29. The probe card according to claim 26, wherein the core is made of a material selected from the group consisting of: silicon nitride, silicon carbide and CVD-D (Chemical Vapor Deposition-Diamond).

30. The probe card according to claim 2, wherein the heat dispersion device further comprises air-cooled heat exchange structures including an exchanger and a fan coil configured to generate cooling air for the exchanger, as well as a core made of a material having a thermal conductivity greater than 100 W/(m·K) and arranged inside the space transformer, the thermal pipe having a first end in thermal contact with the exchanger and a second end in thermal contact with the core.

31. The probe card according to claim 2, wherein the heat dispersion device further comprises liquid-cooled heat exchange structures including a microfluidic channel formed inside the thermal pipe and the space transformer and passed through by a cooling liquid, as well as a core made of a material having a thermal conductivity greater than 100 W/(m·K) and arranged inside the space transformer, the thermal pipe having a first end at an end of the microfluidic channel and a second end in thermal contact with the core.

32. The probe card according to claim 31, wherein the liquid-cooled heat exchange structures include a plurality of microfluidic channels formed inside the thermal pipe and the space transformer.
